(19) United States
(12) Patent Application Publication
(10) Pub. No.: US 2021/0188603 A1
(43) Pub. Date: Jun. 24, 2021

(54) Electric Winch Comprising a Fully Integrated Cooling System

(71) Applicant: Flekkefjord Elektro AS, Flekkefjord (NO)

(72) Inventors: Alf Magne Midtbø Versland, Øyestranda (NO); Johan Ingemann Ellingsen, Kvinesdal (NO); Svein Rune Larsen, Hidrasund (NO); Eirik Fønstelien, Grimstad (NO)

(73) Assignee: Flekkefjord Elektro AS, Flekkefjord (NO)

(21) Appl. No.: 17/263,253

(22) PCT Filed: Jul. 23, 2019
(86) PCT No.: PCT/NO2019/050156

§ 371 Date: Jan. 26, 2021

(30) Foreign Application Priority Data
Jul. 27, 2018 (NO) 20181034

(51) Int. Cl. B66D 1/28; B66D 1/12; B66D 1/14

(52) U.S. Cl. CPC B66D 1/28; B66D 2700/0183; B66D 1/14; B66D 1/12

(57) ABSTRACT

An electric winch has a winch drum and a winch base. The winch drum has a drive train with an electric motor. The winch base has mounting portions being configured for rotatably holding and supporting the winch drum and the drive train. The electric winch further has a liquid-based cooling system. The winch base has a foot portion in between the mounting portions. The liquid-based cooling system is a closed-loop system and is integrated in the foot portion of the electric winch base, mounting portions, and winch drum without requiring connection to further liquid-connection points.

### CROSS-REFERENCE TO RELATED APPLICATIONS

This application is the U.S. national stage application of International Application PCT/NO2019/050156, filed Jul. 23, 2019, which international application was published on Jan. 30, 2020, as International Publication WO 2020/022907 in the English language. The International Application claims priority of Norwegian Patent Application No. 20181034, filed Jul. 27, 2018. The international application and Norwegian application are both incorporated herein by reference, in entirety.

### FIELD OF THE INVENTION

The invention relates to an electric winch comprising a winch drum and a winch base, wherein the winch drum comprises a drive train comprising electric motor, wherein the winch base comprises respective mounting portions being configured for rotatably holding/supporting the winch drum, wherein the electric winch further comprises a liquid-based cooling system.

### BACKGROUND OF THE INVENTION

During the last couple of years, electric motors are getting more and more important. The electric vehicle industry is a clear example, where there has been an explosive growth over the past years and this trend is expected to continue in the years to come. The car industry clearly has been pushing electric motor technology towards smaller dimensions, more efficiency, and higher performance. However, similar trends are now visible in other industry sectors, such as the shipyard industry and, connected therewith, the offshore petroleum industry.

In an increasingly tougher competition, the Norwegian industry depends on developing new high-tech products. A change from hour-demanding production to more technology demanding production will provide Norwegian shipyards with increased competitiveness. One of the main objectives is to develop more compact electric winches. Making winches more compact also leads to challenges in cooling the winch.

Various attempts have been done to obtain compact electric winches. An example of a compact electric winch is disclosed in non-prepublished patent application PCT/NO2018/050187 from the same applicant. One of the challenges with making more compact electric winches is the cooling of the heat-generating parts, such as the electric motor and the gear, particularly when these are placed inside the winch drum. Another challenge is to make the electric winch easy to install and maintain.

### SUMMARY OF THE INVENTION

The invention has for its object to remedy or to reduce at least one of the drawbacks of the prior art, or to at least provide a useful alternative to prior art.

The object is achieved through features, which are specified in the description below and in the claims that follow.

The invention is defined by the independent patent claims. The dependent claims define advantageous embodiments of the invention.

In a first aspect the invention relates to an electric winch comprising a winch drum and a winch base, wherein the winch drum comprises a drive train integrated within the winch, the drive train comprising an electric motor, wherein the winch base comprises respective mounting portions being configured for rotatably holding and supporting the winch drum and the drive train. The electric winch further comprises a liquid-based cooling system. The winch base comprises a foot portion provided in between the mounting portions for connection of said mounting portions. Said liquid-based cooling system is a closed-loop system and has been integrated in said foot portion of the electric winch base, mounting portions, and winch drum without requiring connection to further liquid-connection points in order to operate. The liquid-based cooling system comprises: a pump for circulating liquid, a heat-exchanger, and flowlines for connecting said pump and heat-exchanger to form the closed-loop system, wherein the heat-exchanger is placed in thermal communication with the electric motor inside the winch drum. The liquid-based cooling system further comprises a first reservoir in fluid-communication with the heat-exchanger, the first reservoir being configured for receiving heated liquid from the heat-exchanger, the liquid-based cooling system further comprising a second reservoir in fluid-communication with both the first reservoir and the pump, the second reservoir being configured for containing cooled liquid for being pumped to the heat-exchanger via the pump, wherein said reservoirs are placed in the foot portion of the winch base.

In order to facilitate understanding of the invention one or more expressions, used throughout this specification, are further defined hereinafter.

Wherever the wording “winch drum” is used, this is to be interpreted as the part of the winch onto which the wire is (to be) wound. The winch drum typically feeds and spools the wire in operational use.

Wherever the wording “drive train” is used, this is to be interpreted as the part of the winch which creates the torque for driving the winch drum. This includes a motor, but may also include a gear if present.

Wherever the wording “winch base” is used, this is to be interpreted as the mechanical part of the winch which supports and holds the winch drum, the drive line and a torque-transmitting device, if present.

Wherever the wording “mounting portion” is used, this is to be interpreted as that part of the winch base wherein the winch drum is rotatably mounted, conventionally via respective bearings.

Wherever the wording “liquid-based cooling system” is used, this is to be interpreted as cooling systems which circulate a liquid medium to exchange heat with heat-generating parts and to release heat with cooling parts (including heatsinks).

Wherever the wording “closed-loop cooling system” is used, this is to be interpreted as a cooling system that stands on its own, i.e. does not need to be connected to a further liquid connection points (source or drain) in order to operate.

Wherever the wording “cooling unit” is used, this is to be interpreted as any apparatus or module, which is capable of reducing the temperature of the (warm) medium which runs through it or is in thermal communication with it. Examples of such cooling units are: radiators, heat-exchangers, piezo-coolers, heatsinks, cooling plates, etc.

The effects of the electric winch in accordance with the invention are as follows. The drive train may create a lot of heat (generally the main part of the heat) during operational use. When this drive train is integrated into the winch drum it may be very difficult, or virtually impossible, to get rid of this heat via radiation and convection. Therefore, the electric winch needs a cooling system as is the case for the current invention. In prior art solutions this cooling system requires connection of the cooling system to all sorts of liquid-connection points. First of all, the electric winch of the current invention does not require connection with any further liquid-connection points, which turns the electric winch into an easily-installable module, which only needs to be connected to the electric grid. This advantage is because of the integration of the cooling system as a closed-loop system and providing all parts in the winch base, mounting portions and winch drum. After physically placing the electric winch at the desired location, the only requirement is to connect the electric winch to the electric grid. In addition, maintenance has become much easier as well, because of the modular concept of the electric winch of the invention.

The invention provides an efficient way of cooling the electric motor. Because pipe lengths are short in the cooling system of the invention, pressure losses are less and consequently the pump may be designed smaller.

Furthermore, in the invention the separation of heated water and cooled water provides for a more efficient cooling of the electric motor.

In an embodiment of the electric winch in accordance with the invention the liquid-based cooling system further comprises a cooling unit placed in between and in fluid communication with the first reservoir and the second reservoir, wherein the cooling unit is placed in the foot portion of the winch base, the cooling unit being configured: i) for receiving said heated liquid from the first reservoir; ii) for cooling down said heated liquid to obtain said cooled liquid, and iii) for providing said cooled liquid to the second reservoir. The cooling unit provided in between the reservoirs further increases the efficiency of the cooling system.

In an embodiment of the electric winch in accordance with the invention the drive train comprises a gear system provided within the winch drum, wherein the liquid-based cooling system also comprises a further heat-exchanger placed in thermal communication with the gear system inside the winch drum. In this embodiment the cooling system is effectively used for cooling both the electric motor and the gear system, which may also generate heat due to the rotating parts therein. The earlier-mentioned pump may be used to pump the liquid through the further heat-exchanger. Alternatively, a dedicated pump may be used for each of the electric motor and the gear system.

An embodiment of the electric winch in accordance with the invention further comprises a further drive train comprising a further electric motor within the winch drum, wherein the liquid-based cooling system is also configured for cooling the further electric motor similar to the cooling of the other electric motor.

In an embodiment of the electric winch in accordance with the invention further comprises at least two sub-reservoirs within each reservoir. The advantage of this embodiment is that said sub-reservoirs open up the possibility of assigning different roles to said sub-reservoirs, i.e. to contain heated liquid for the first drive train, cooled liquid for the first drive train, heated liquid for the second drive train and cooled liquid for the second drive train. This allows for much more sophisticated cooling flows, and multiple loops. This will be further elaborated upon in the detailed description of the figures.

In an embodiment of the electric winch in accordance with the invention the cooling system further comprises a flow control system coupled between said reservoirs and sub-reservoirs, the flow control system comprising valves for controlling the flow and flow direction of the cooling liquid in operational use in dependence of the actual need for cooling due to heat-generating parts. Such flow control system makes the cooling system effective and allows for tailor-made cooling of the respective heat-generating parts of the electric winch, which are the electric motor and the gear in particular. This will be further elaborated upon in the detailed description of the figures.

### BRIEF INTRODUCTION OF THE DRAWINGS

In the following is described examples of embodiments illustrated in the accompanying drawings, wherein:

FIG. 1 shows a front view of a first embodiment of an electric winch in accordance with the invention;

FIG. 2 shows a transparent perspective view of the electric winch of FIG. 1;

FIG. 3 shows a perspective cut view of the electric winch of FIG. 1;

FIG. 4 shows a transparent left side view of FIG. 3;

FIG. 5 shows one half of the electric winch of FIG. 1;

FIG. 6 shows part of the cooling system of the electric winch of FIG. 5;

FIG. 7 shows a hydraulic scheme of the cooling system of the electric winch of FIG. 1;

FIG. 8 illustrates flow directions in the hydraulic scheme of FIG. 7;

FIG. 9 shows a transparent perspective view of a second embodiment of the electric winch in accordance with the invention, wherein some parts of the winch drum have been left out;

FIG. 10 shows a perspective view of the electric winch of FIG. 9, wherein the mounting portions of the winch foundation have been left out;

FIG. 11 shows a top view of the winch base, wherein the cooling system in accordance with the second embodiment has been further illustrated;

FIG. 12 shows a transparent front view of the electric winch of FIG. 9; and

FIGS. 13-22 show various operational modes of the cooling system in accordance with the second embodiment as shown in FIG. 11.

### DETAILED DESCRIPTION OF THE EMBODIMENTS

Various illustrative embodiments of the present subject matter are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various systems, structures and devices are schematically depicted in the drawings for purposes of explanation only and so as not to obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e. a definition that is different from the ordinary and customary meaning as understood by those skilled in the art, is intended to be implied by consistent usage of the term or phrase herein. To the extent that a term or phrase is intended to have a special meaning, i.e. a meaning other than that understood by skilled artisans, such a special definition will be expressly set forth in the specification in a definitional manner that directly and unequivocally provides the special definition for the term or phrase.

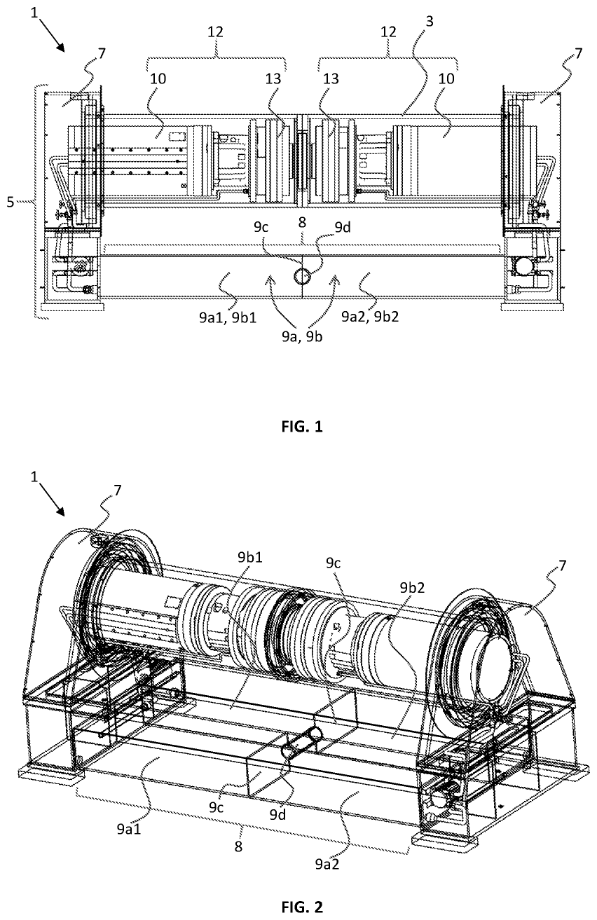

FIG. 1 shows a front view of a first embodiment of an electric winch 1 in accordance with the invention. FIG. 2 shows a transparent perspective view of the electric winch of FIG. 1. The electric winch 1 comprises a winch drum 3 mounted on a winch base 5, which comprises mounting portions 7 connected via a foot portion 8 as shown in the figures. The mounting portions 7 are configured for rotatably supporting the winch drum 3. The electric winch 1 of this embodiment comprises two drive trains 12, wherein each drive train 12 comprises an electric motor 10 coupled in series with a gear 13 as illustrated. Both the electric motor 10 and the gear 13 of each drive train 12 have been integrated within the winch drum 3. There may also be provided a torque transmitting device (not shown in any one of the figures). In all disclosed embodiments this may be a torque-transmitting tube, wherein said drive trains 12 are placed, wherein the torque-transmitting tube on it turn is provided within the winch-drum 3. However, it must be born in mind that both the electric motor 10 and the gear 13 may be designed such that they have the torque-transmitting function integrated in them. This may be achieved by using mechanically strong housings for those components, for example. FIGS. 1 and 2 further show a liquid-based cooling system integrated as a closed-loop system within the foot portion 8, the mounting portions 7 and the winch drum 3. This cooling system will be further elaborated upon with reference to other figures. What may be derived from FIGS. 1 and 2 is that an important ingredient of the invention is to integrate a first reservoir 9a and a second reservoir 9b in the foot portion 8. In this embodiment the first reservoir 9a is divided in two sub-reservoirs 9a1, 9a2 by a separating wall 9c inside said reservoir 9a as illustrated. Similarly, the second reservoir 9b is divided in two sub-reservoirs 9b1, 9b2 by a separating wall 9c inside said reservoir 9b as illustrated. A further element of the invention resides in the shared flowline 9d in between said reservoirs 9a, 9b. The shared flowline 9d is placed such that it connects all sub-reservoirs 9a1, 9a2, 9b1, 9b2 together. Alternatively, a dedicated flowline may be used for each pair of sub-reservoirs. In a further alternative the shared flowline 9d and/or the separating walls 9c are left out. This will influence the flow directions that are possible in the cooling system. The advantage of the configuration of FIGS. 1 and 2 is that the cooling liquids of said two drive trains blend during operational use, which may result in a more homogenous temperature of said drive trains. A disadvantage is the reduced ability to individually control the cooling effect for each drive train 12.

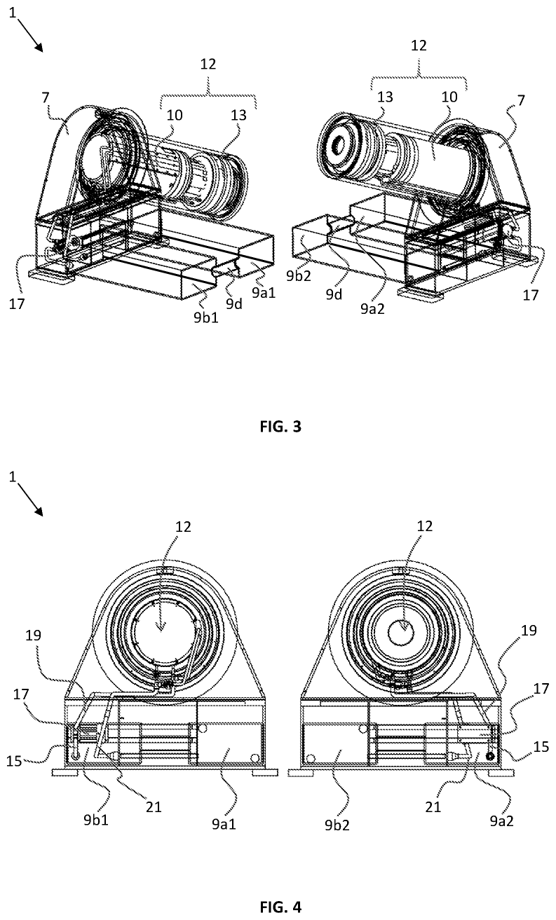

FIG. 3 shows a perspective cut view of the electric winch of FIG. 1. FIG. 4 shows a transparent left side view of FIG. 3. These figures illustrate more clearly the liquid-based cooling system in accordance with the invention. These figures illustrate a hydraulic pump 17 in each mounting portion 7 of the winch 1. FIG. 3 also illustrates the size and relative position of the sub-reservoirs 9a1, 9a2, 9b1, 9b2 and their shared flowline 9d (cut in two halves in FIG. 3). Further is shown that in each half of the winch a respective hydraulic flowline 15 connects one of said sub-reservoirs 9b1, 9a2 to said pump 17. Then there is illustrated a further hydraulic flowline 19 from said pump 17 that runs to the drive train 12 and return flowlines 21 that run from the drive train 12 to the other one of said sub-reservoirs 9a1, 9b2.

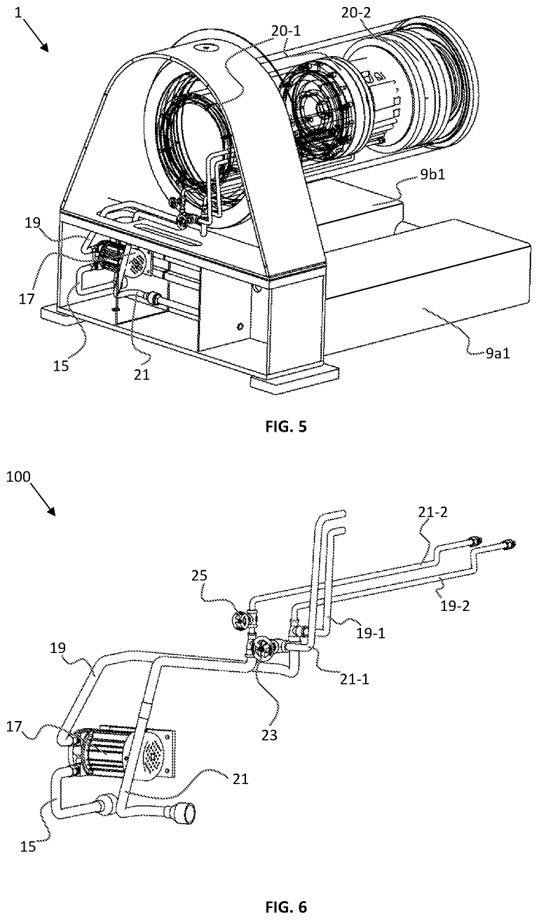

FIG. 5 shows one half of the electric winch 1 of FIG. 1. The figure mainly shows the cooling system 100 of the electric winch 1. The motor and gear have been left out for illustrative purposes. The other half has a similar configuration. FIG. 6 shows part of the cooling system of the electric winch of FIG. 5. These figures illustrate the earlier discussed pump 17 and flowlines 15, 19, 21 in more detail. FIG. 5 shows that there is a first heat-exchanger 20-1 for placement around the electric motor 10 and a second heat-exchanger 20-2 for placement around the gear 13. FIG. 6 shows that said hydraulic flowline 19 that runs from the pump 17 is split in two hydraulic lines, namely an inlet flowline 19-1 for the first heat-exchanger 20-1 and an inlet flowline 19-2 for the second heat-exchanger 20-2. Similarly, the return flowline 21 is connected with a first outlet flowline 21-1 running from the first heat-exchanger 20-1 and a second outlet flowline 21-2 running from the second heat-exchanger 20-2. Said outlet flowlines 21-1, 21-2 terminate in a respective flow/pressure regulation valve 23, 25. Downstream said flow/pressure regulation valve 23, 25 said outlet flowlines 21-1, 21-2 are coupled into said return flowline 21.

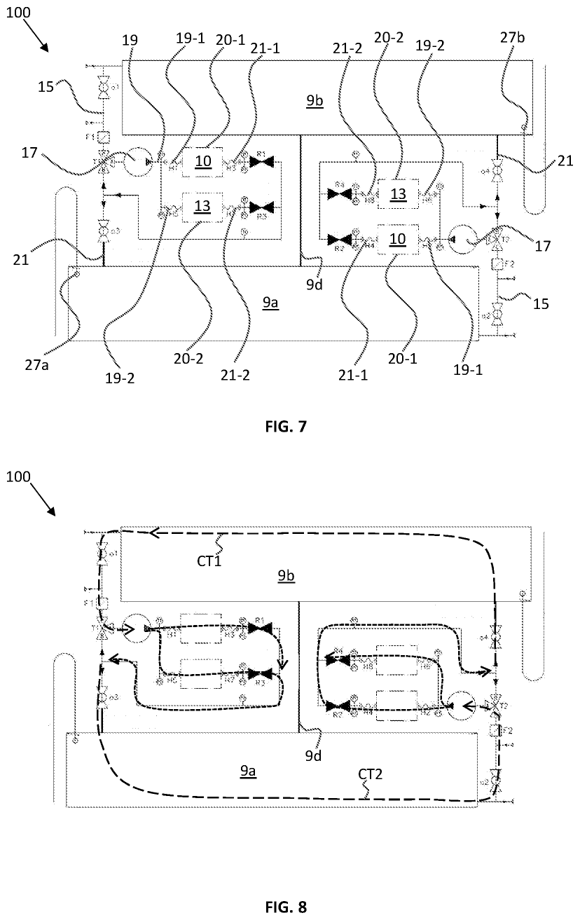

FIG. 7 shows a hydraulic scheme of the cooling system 100 of the electric winch 1 of FIG. 1 in accordance with the first embodiment of the invention. The figure shows a possible hydraulic configuration of earlier mentioned first reservoir 9a and second reservoir 9b, shared flowline 9d, pumps 17, heat-exchangers 20-1, 20-2, and hydraulic flowlines 15, 17, 19, 19-1, 19-2, 21, 21-1, 21-2. The figure also illustrates that each reservoir 9a, 9b has a respective fill inlet/breathing tube 27a, 27b. In the configuration of FIG. 7 the left pump 17 is coupled with its suction side to the second reservoir 9b (upper reservoir) and the right pump 17 is coupled with its suction side to the first reservoir 9a (lower reservoir).

FIG. 8 illustrates flow directions in the hydraulic scheme of FIG. 7. The figure shows a first cooling flow CT1 for the first drive train 12 illustrated with dashed arrows on the left side and top side of the figure. The figure also shows a second cooling flow CT2 for the second drive train 12 illustrated with dashed arrows on the right side and bottom side of the figure. It must be noted that in the embodiment of FIG. 8 the shared flowline 9d between the reservoirs 9a, 9b is not effectively used. However, it must be noted that it is possible to connect the suction side of the pump 17 to any one of said reservoirs 9a, 9b thereby reconfiguring the flow directions within the hydraulic diagram. Also, the cooling system 100 may comprise additional flowlines between said reservoirs for allowing other flow configurations, wherein said shared flowline 9d is used. These variations are applicable to all embodiments shown and discussed in this specification.

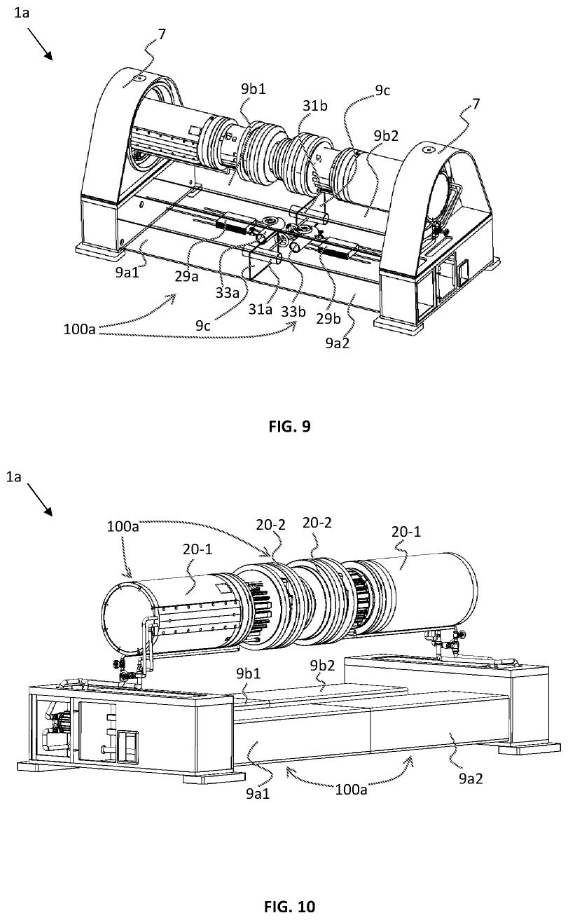

FIG. 9 shows a transparent perspective view of a second embodiment of the electric winch 1a in accordance with the invention, wherein some parts of the winch drum 3 have been left out. The figure mainly illustrates the cooling system 100a in accordance with the second embodiment of the invention. FIG. 10 shows a perspective view of the electric winch of FIG. 9, wherein the mounting portions of the winch foundation have been left out. The main differences between this embodiment and the first mentioned embodiment are that the cooling system 100a comprises one radiator 29a, 29b for each drive train 12. Instead of radiators 29a, 29b also other types of heat-exchangers may be used. Similar to the first embodiment there is provided separating walls 9c inside the first and second reservoir. The cooling system 100a does not comprise a shared flowline in between said reservoirs 9a1, 9a2, 9b1, 9b2. Instead there is provided a first bypass valve 33a connecting the first sub-reservoir 9a1 of the first reservoir 9a with the first sub-reservoir 9b1 of the second reservoir 9b, as illustrated. Furthermore, there is provided a second bypass valve 33b connecting the second sub-reservoir 9a2 of the first reservoir 9a with the second sub-reservoir 9b2 of the second reservoir 9b, as illustrated. Also, there are provided a first reservoir connecting valve 31a in the separating wall 9c of the first reservoir 9a and a second reservoir connecting valve 31b in the separating wall 9c of the second reservoir 9b. FIG. 10 shows how the respective flowlines are coupled to the respective heat-exchangers 20-1, 20-2.

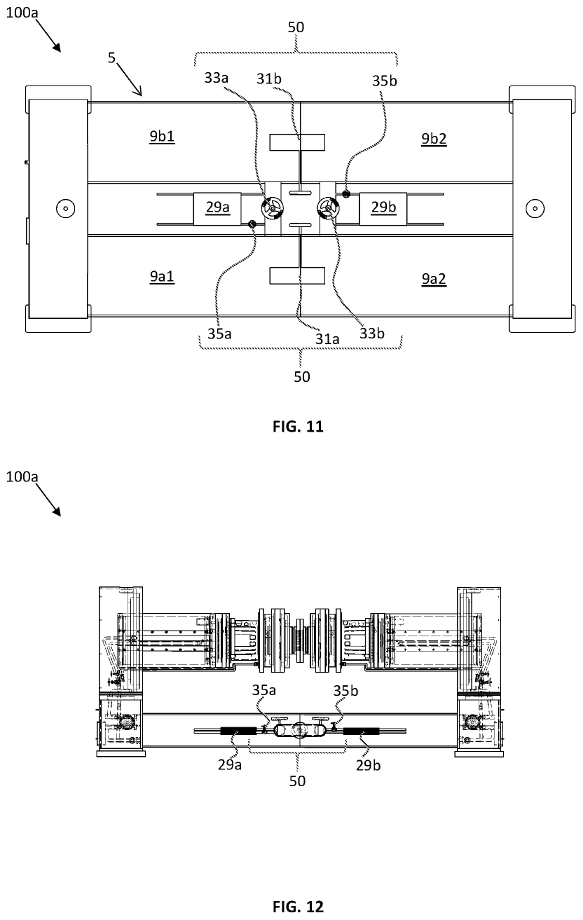

FIG. 11 shows a top view of the winch base 5, wherein the cooling system 100a in accordance with the second embodiment has been further illustrated. FIG. 12 shows a transparent front view of the electric winch of FIG. 9. The figures illustrates the placement of the respective reservoir connecting valves 31a, 31b and bypass valves 33a, 33b. The figure also illustrates further selection valves 35a, 35b provided in the flowlines that connect the radiators 29a, 29b. The combination of all valves is also referred to as the flow control system 50 in this embodiment. All valves 31a, 31b, 33a, 33b can be selectively opened and closed. In the figures the valves have been illustrated as manually operated valves, but these valves may also be implemented as (semi)-automatic and/or remotely operated valves. The valves make it possible to determine the flow direction of the cooling liquid in many different ways. Also, the selection valves 35a, 35b make it possible to bypass or select the radiators 29a, 29b individually. It must be borne in mind that the flow direction also determines which reservoir gets the function of holding heated liquid and which reservoir gets the function of cooled liquid.

For the cooling liquid many different options exist. In the current examples water is used as a cooling liquid, because it has a relatively high heat capacity. The water may further contain several additives to prevent corrosion and/or frost as is known in the technical field of cooling systems.

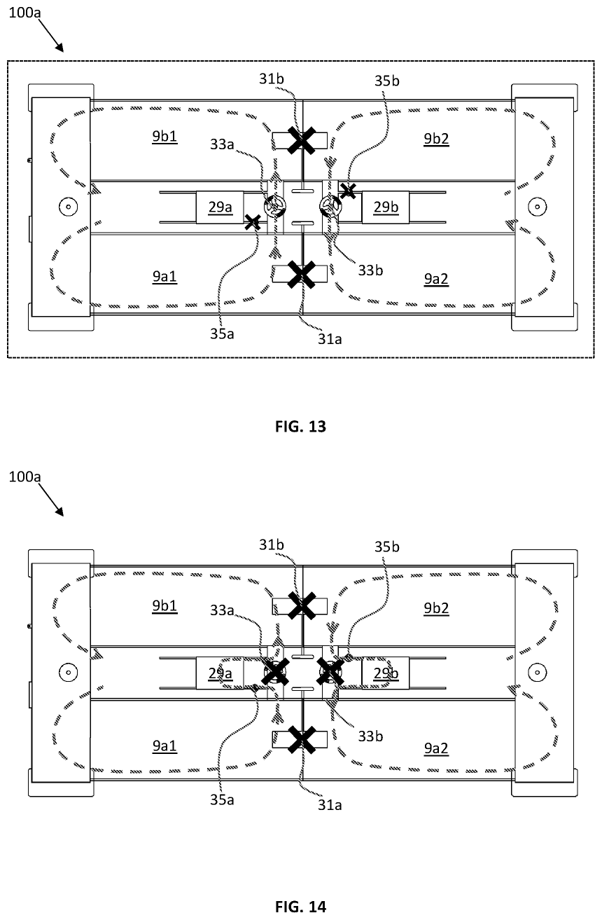

FIGS. 13-22 show various operational modes of the cooling system in accordance with the second embodiment as shown in FIG. 11. The list of illustrated modes is just illustrative and not exhaustive. There are many more modes possible.

FIG. 13 shows an operational mode, wherein both radiators 29a, 29b have been deactivated by closing both selection valves 35a, 35b as illustrated by the crosses. Furthermore, said sub-reservoirs 9a1, 9a2, 9b1, 9b2 are isolated from each other, because of said reservoir connecting valves 31a, 31b being closed (which is also the case for FIGS. 14-16). Consequently, the cooling flows circulate as illustrated by the arrows bypassing the radiators through said bypass valves 33a, 33b which are open in this operational mode. The flow through the heat-exchangers is not shown in FIGS. 13-22 in order to simplify understanding of the invention. In FIG. 13 the first sub-reservoir 9a1 of the first reservoir contains heated liquid (coming from the heat-exchangers (not shown)), while the first sub-reservoir 9b1 of the second reservoir 9b contains cooled liquid (or at least cooler liquid). The second sub-reservoir 9a2 of the first reservoir 9a contains cooled liquid (or at least cooler liquid) and the second sub-reservoir 9b2 of the second reservoir 9b contains heated liquid (coming from the heat-exchangers (not shown)).

FIG. 14 shows an operational mode, wherein both radiators 29a, 29b have been activated by opening both selection valves 35a, 35b and closing both reservoir connecting valves 31a, 31b as illustrated. Consequently, the cooling flows circulate as illustrated by the arrows now running through the radiators. The result is that in operational mode there will be a stronger temperature drop of the cooling liquid when running from between the reservoirs (from hot to cold).

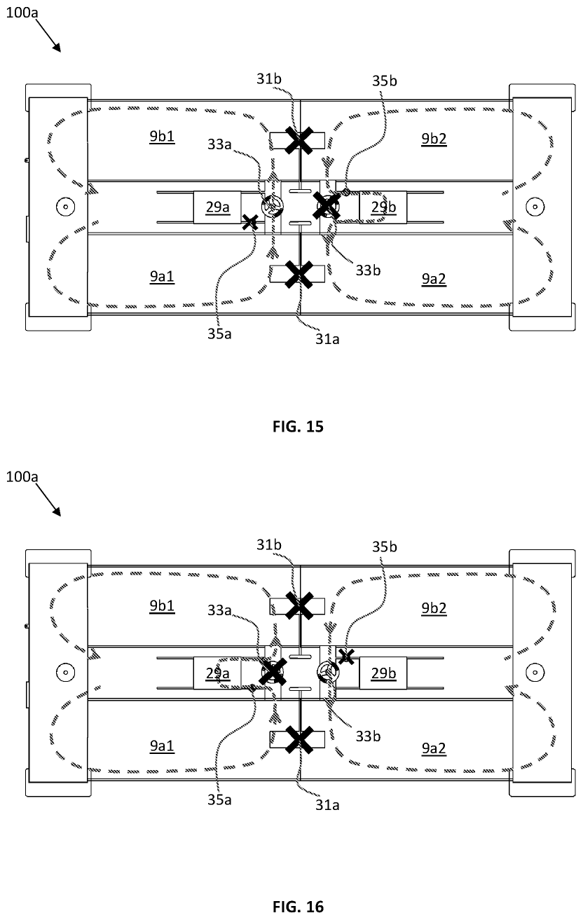

FIG. 15 shows an operational mode, wherein only the right radiator 29b is used and the left radiator is bypassed by proper opening and closing of said valves as illustrated. FIG. 16 shows an operational mode, wherein only the left radiator 29a is used and the right radiator is bypassed through proper opening and closing of said valves as illustrated. These operational modes may be used when only one drive train is used during use of the winch.

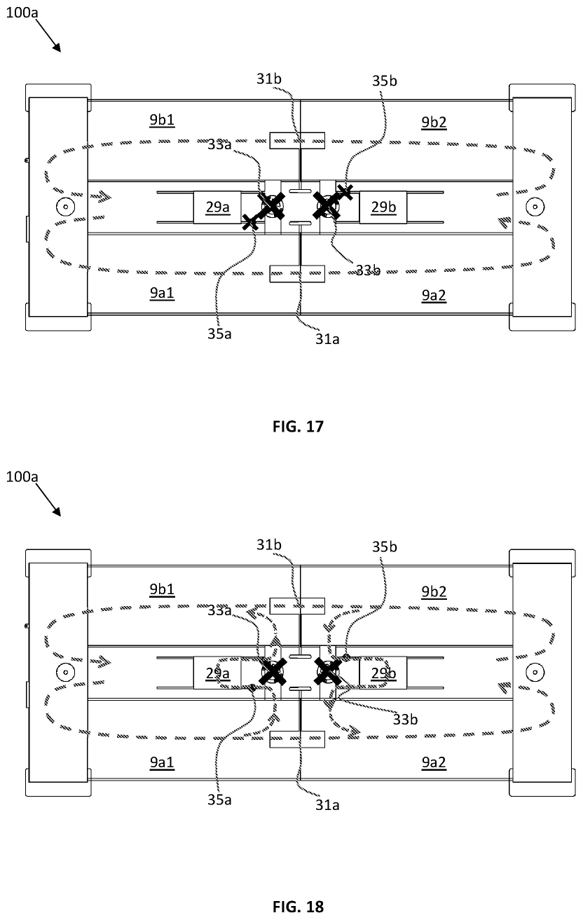

FIG. 17 shows an operational mode, wherein said sub-reservoirs are connected by opening said reservoir connecting valves 31a, 31b. Furthermore, all bypass valves and selection valves are closed, deactivating both radiators 29a, 29b. Consequently, the cooling flows circulate as illustrated below. In FIG. 17 the first sub-reservoir 9a1 of the first reservoir 9a contains heated liquid (coming from the heat-exchangers (not shown)), while the second sub-reservoir 9a2 of the first reservoir 9a contains cooled liquid (or at least cooler liquid). The first sub-reservoir 9b1 of the second reservoir 9b contains cooled liquid (or at least cooler liquid) and the second reservoir 9b2 of the second reservoir contains heated liquid (coming from the heat-exchangers (not shown)).

FIG. 18 shows an operational mode, wherein both radiators 29a, 29b have been activated by opening said selection valves 35a, 35b. Consequently, extra flow paths running through said radiators 29a, 29b are created. This will reduce the liquid temperature in said second sub-reservoir 9a2 of the first reservoir 9a and the first sub-reservoir 9b1 of the second reservoir 9b as the cooled liquid from the radiators 29a, 29b blends with the hotter liquid coming from the other sub-reservoir.

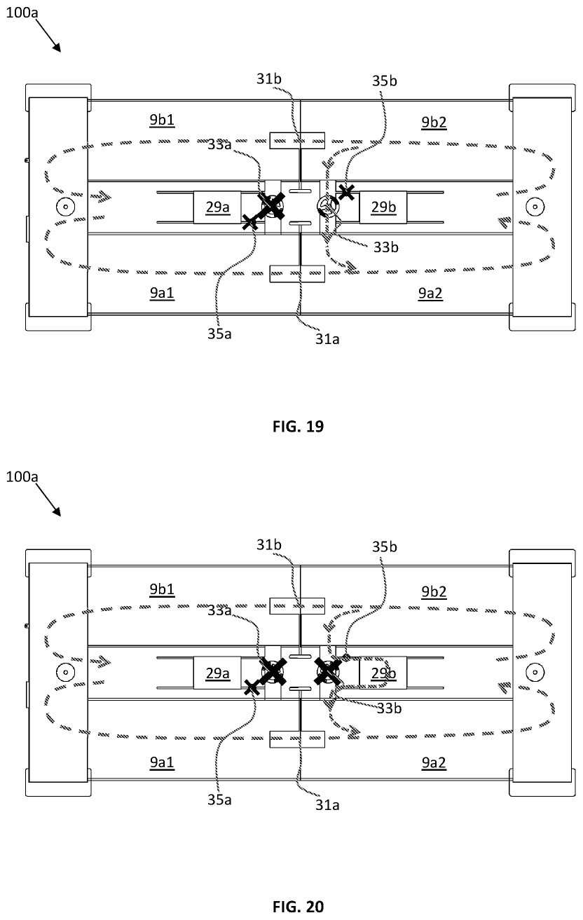

FIG. 19 shows an operational mode, wherein both radiators 29a, 29b have been deactivated by closing said selection valves 35a, 35b. However, one of said bypass valves 33b has been opened to create a bypass for said cooling liquid coming from the second sub-reservoir 9b2 of the second reservoir 9b. Even though the radiator is not activated, this still will result in a lowering of the temperature of the liquid in the second sub-reservoir 9a2 of the first reservoir 9a.

FIG. 20 shows an operational mode, wherein, compared to the mode in FIG. 19, the right radiator 29b has been activated by opening said selection valve 35b and closing said bypass valve 33b as illustrated. Both the operational mode of FIG. 19 and FIG. 20 may be used in case only one drive train 12 (here in the right drive train) is used and needs cooling.

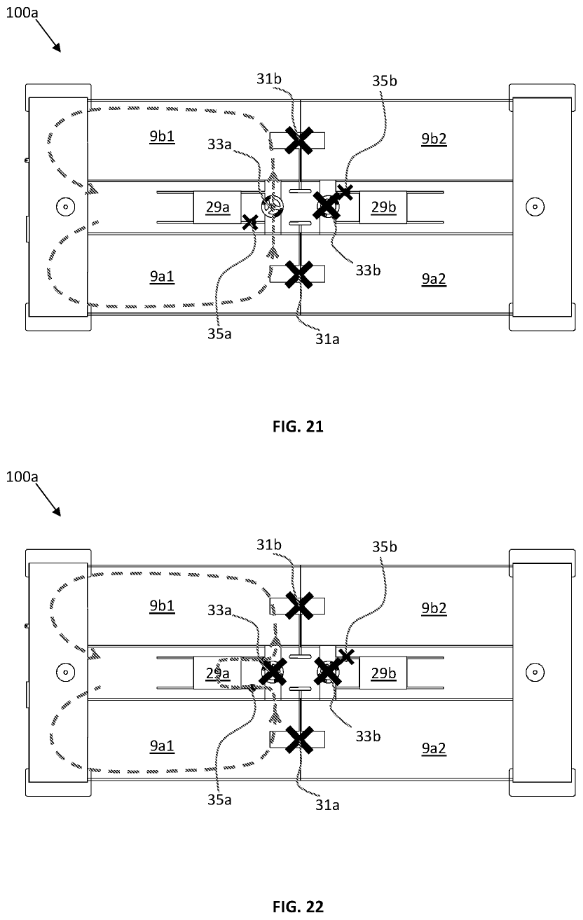

FIG. 21 shows an operational mode, wherein only one drive train 12 is used (the left one), and wherein the cooling system 100a only circulates on the left side. The radiator 29a is deactivated and the cooling flow runs as illustrated.

FIG. 22 shows an operational mode, wherein, compared to FIG. 21, the left radiator 29a is activated forcing the cooling flow through the radiator.

FIGS. 13-22 clearly show the enormous amount of variations and modes that are made possible by placing a valve control system 50 with valves in and in between the reservoirs. It makes the cooling system more effective and allows for tailor-made cooling of the respective heat-generating parts of the electric winch, which are the electric motor and the gear in particular.

As a general rule it must be said that an extra radiator to cool said cooling liquid is not essential but an option to the invention. The extra radiator makes the cooling system more effective and thereby allow for higher power to be generated by the electric motor and more warmth to be generated by the gear.

By way of illustration, the invention can be used all kinds of winch systems, such as cranes, cargo and person elevators, drill towers, oilrigs, boat cranes, transport vehicles, floating vessels and boats, storage drums and all kinds of other winch and spooling devices for spooling other things than cables, wires and tubular structures. Another application area where the invention may be advantageously applied is airborne wind energy. In this application the installation of pipelines for circulating cooling liquid (water) through the winches is completely dispensed with. Installation of airborne wind turbines is thereby made a lot easier.

The particular embodiments disclosed above are illustrative only, as the invention may be modified and practiced in different but equivalent manners apparent to those skilled in the art having the benefit of the teachings herein. For example, the method steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope of the invention. Accordingly, the protection sought herein is as set forth in the claims below.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The mere fact that certain measures are recited in mutually different dependent claims does not indicate that a combination of these measures cannot be used to advantage. In the device claim enumerating several means, several of these means may be embodied by one and the same item of hardware.

1.-8. (canceled)

9. An electric winch comprising:
a winch drum and a winch base,
wherein the winch drum comprises a drive train integrated within the winch drum, the drive train comprising an electric motor,
wherein the winch base comprises respective mounting portions being configured for rotatably holding and supporting the winch drum and the drive train,
wherein the electric winch further comprises a liquid-based cooling system,
wherein the winch base comprises a foot portion provided in between the mounting portions for connection of said mounting portions, and
wherein said liquid-based cooling system is a closed-loop system and has been integrated in said foot portion of the electric winch base, mounting portions, and winch drum without requiring connection to further liquid-connection points in order to operate,
wherein the liquid-based cooling system comprises:
a pump for circulating liquid, a heat-exchanger, and flowlines for connecting said pump and heat-exchanger to form the closed-loop system,
wherein the heat-exchanger is placed in thermal communication with the electric motor inside the winch drum, and
wherein the liquid-based cooling system further comprises a first reservoir in fluid-communication with the heat-exchanger, the first reservoir being con-figured for receiving heated liquid from the heat-exchanger, the liquid-based cooling system further comprising a second reservoir in fluid-communication with both the first reservoir and the pump, the second reservoir being configured for containing cooled liquid for being pumped to the heat-exchanger via the pump, wherein said reservoirs are placed in the foot portion of the winch base.

10. The electric winch according to claim 9, wherein the liquid-based cooling system further comprises a cooling unit placed in between and in fluid communication with the first reservoir and the second reservoir, wherein the cooling unit is placed in the foot portion of the electric winch base, the cooling unit being configured:
for receiving said heated liquid from the first reservoir;
for cooling down said heated liquid to obtain said cooled liquid, and
for providing said cooled liquid to the second reservoir.

11. The electric winch according to claim 9, wherein the drive train further comprises a gear system provided within the winch drum, wherein the liquid-based cooling system also comprises a further heat-exchanger placed in thermal communication with the gear system inside the winch drum.

12. The electric winch according to claim 9, further comprising a further drive train comprising a further electric motor within the winch drum, wherein the liquid-based cooling system is also configured for cooling the further electric motor similar to the cooling of the other electric motor.

13. The electric winch according to claim 12, wherein the cooling system further comprises at least two sub-reservoirs within each reservoir.

14. The electric winch according to claim 13, wherein the cooling system further comprises a flow control system coupled between said reservoirs and sub-reservoirs, the flow control system comprising valves for controlling the flow and flow direction of the cooling liquid in operational use in dependence of the actual need for cooling due to heat-generating parts.

15. The electric winch according to claim 10, wherein the drive train further comprises a gear system provided within the winch drum, wherein the liquid-based cooling system also comprises a further heat-exchanger placed in thermal communication with the gear system inside the winch drum.

16. The electric winch according to claim 10, further comprising a further drive train comprising a further electric motor within the winch drum, wherein the liquid-based cooling system is also configured for cooling the further electric motor similar to the cooling of the other electric motor.

17. The electric winch according to claim 11, further comprising a further drive train comprising a further electric motor within the winch drum, wherein the liquid-based cooling system is also configured for cooling the further electric motor similar to the cooling of the other electric motor.
